(19) United States
(12) Patent Application Publication
(10) Pub. No.: US 2018/0102326 A1
(43) Pub. Date: Apr. 12, 2018

(54) Perimeter Control Of Crack Propagation In Semiconductor Wafers

(71) Applicant: United Silicon Carbide, Inc., Monmouth Junction, NJ (US)

(72) Inventor: William Kurt Simon, Lebabon, NJ (US)

(21) Appl. No.: 15/730,834

(22) Filed: Oct. 12, 2017

Related U.S. Application Data
(60) Provisional application No. 62/407,226, filed on Oct. 12, 2016.

(51) Int. Cl. H01L 23/00; H01L 23/498; H01L 21/304

(52) U.S. Cl. CPC H01L 23/562; H05K 1/0213; H01L 21/3043; H01L 23/49833

(57) ABSTRACT

A semiconductor substrate such as a wafer includes a scoring that is inset from the perimeter. The scoring follows the perimeter or a portion thereof. The scoring may take the form of a groove or a trench on one or more surfaces of the wafer, a void or a lattice defect in the interior of the wafer, a series of perforations, or a combination thereof. A groove may be formed by dicing/sawing. A trench or series of perforations may be formed via etching or ablation. Voids or lattice defects may be introduced by laser treatment or ion bombardment.

### CROSS-REFERENCE TO RELATED APPLICATIONS

This application claims the benefit of U.S. Provisional Patent Application Ser. No. 62/407,226 filed Oct. 12, 2016, titled “Perimeter control of crack propagation in semiconductor wafers,” the disclosure of which is hereby incorporated by reference as if set forth in its entirety herein.

### BACKGROUND

Wafers made of semiconductor materials, such as silicon carbide, gallium arsenide, and sapphire, for example, may be susceptible to cracking during processing.

### SUMMARY

A semiconductor substrate such as a wafer includes a scoring that is inset from the perimeter. The scoring follows the perimeter or a portion thereof. The scoring may take the form of a groove or a trench on one or more surfaces of the wafer, a void or a lattice defect in the interior of the wafer, a series of perforations, or a combination thereof. A groove may be formed by dicing/sawing. A trench or a series of perforations may be formed via etching or ablation. Voids or lattice defects may be introduced by laser treatment or ion bombardment.

This summary is provided to introduce a selection of concepts in a simplified form that are further described below in the detailed description. This summary is not intended to identify key features or essential features of the claimed subject matter, nor is it intended to be used to limit the scope of the claimed subject matter. Furthermore, the claimed subject matter is not limited to limitations that solve any or all disadvantages noted in any part of this disclosure.

### BRIEF DESCRIPTION OF THE FIGURES

A more detailed understanding may be had from the following description, given by way of example in conjunction with the accompanying figures. The figures are not necessarily drawn to scale.

FIG. 1 is a top view of a prior art wafer with weakened regions intended to guide cracks deliberately introduced for die singulation.

FIG. 2 is a top view of a prior art wafer with trenches intended to protect the individual die from accidental cracks introduced during singulation.

FIG. 3 is a top view of an example wafer with an intentionally weakened region at the perimeter of the wafer to counter propagation of accidental/unintentional edge cracks.

FIGS. 4 is cross section of an edge portion of an example wafer, showing an intentionally weakened region in the form of a V-shaped notch on the surface of the wafer.

FIGS. 5 is cross section of an edge portion of an example wafer, showing an intentionally weakened region in the interior of the wafer.

FIGS. 6 is cross section of an edge portion of an example wafer, showing an intentionally weakened region in the form of a chamfered notch on the surface of the wafer.

FIG. 7 describes the way in which unintentional edge cracks due to processing and handling will be diverted into the crack-stop and away from the center of the wafer.

### DETAILED DESCRIPTION

A semiconductor substrate such as a wafer may be protected against unintended cracking by incorporating a scoring that is inset from the perimeter. The scoring follows the perimeter or a portion thereof. The scoring may take the form of a groove or a trench on one or more surfaces of the wafer, a void or a lattice defect in the interior of the wafer, a series of perforations, or a combination thereof. A groove may be formed by dicing/sawing. A trench or a series of perforations may be formed via etching or ablation. Voids or lattice defects may be introduced by laser treatment or ion implantation or bombardment.

Thin, brittle, or otherwise weak substrates of semiconductor materials such as silicon carbide (SiC), gallium arsenide (GaAs), and sapphire, may be susceptible to yield loss due to cracking during wafer processing. The use of crack propagation reduction technologies may reduce yield loss, and thereby reduce the average cost of products made on these substrates, such as transistors for power and radio frequency (RF) applications, optoelectronics, photovoltaics, and optical display screens, for example.

The propagation of cracks at the wafer edge may be controlled by placing regions of low strength near the perimeter of the wafer to divert cracks. Regions of low strength may be created by a number of techniques, including surface laser ablation, mechanical or chemical removal of material to create thinner regions, for example. Alternatively, regions of low strength may be induced beneath the surface of the wafer, e.g., by introducing voids in the material or interruptions of the crystal lattice inside the wafer. Placing regions of low strength near the perimeter of the wafer protects the entire wafer, including any chips or other structures thereon, during a multitude of processing steps.

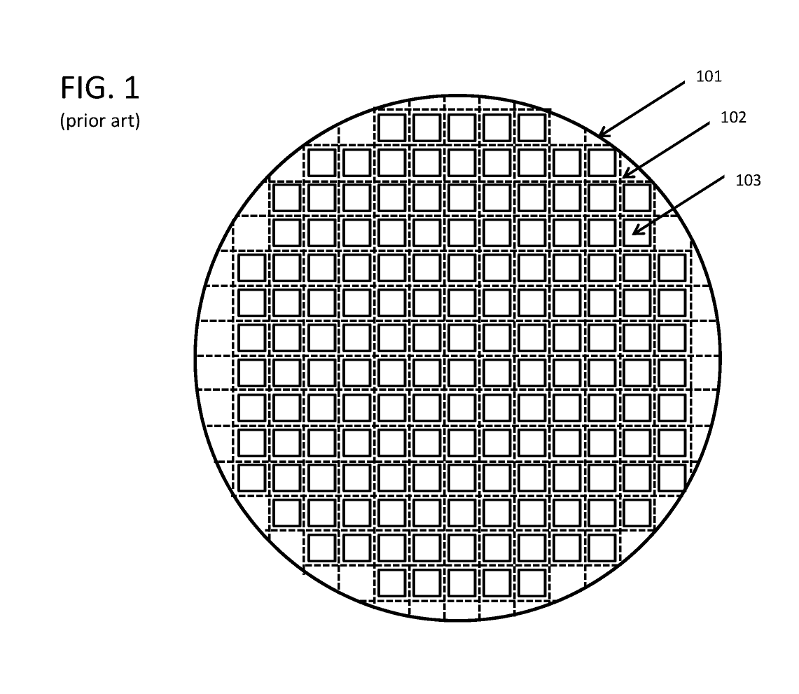

FIG. 1 is a top view of a prior art wafer 101 with weakened regions 102 intended to guide cracks for singulation of dies 103. There may be a large number of dies 103, or chips, on a single wafer 102. Before use, the dies 103 are normally separated from each other and from the remainder of the wafer 101, i.e., “singulated.”

In FIG. 1, the perimeter of the wafer 101 is shown as a large circle. Each die 103 is shown as a small square. The weakened regions 102 are shown as dashed lines running between the dies 103. The weakened regions 102 may be used to confine intentionally created cracks, i.e., to define paths for the propagation of cracks, allowing the singulation of the wafer 101 by cracking the dies 103 apart from each other.

The weakened regions 102 may be created by, e.g., etching, sawing, or laser ablation partially through the thickness of the wafer. The weakened regions 102 may take the form of V-shaped grooves in the surface of the wafer 101. Alternatively, the weakened regions 102 may take the form of sub-surface damage deliberately introduced to the wafer, e.g., via “stealth dicing,” for example.

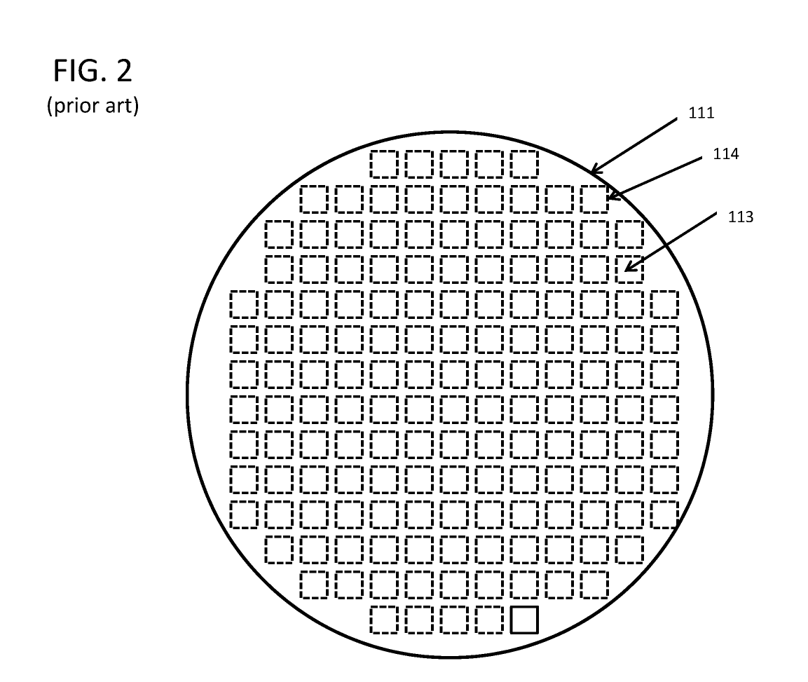

FIG. 2 is a top view of a prior art wafer 111 with weakened lines 114 that surround unweakened areas 113. Dies are located in the unweakened areas 113. This configuration may be used, for example, to prevent cracks from propagating before or during singulation that is done by dicing. The weakened areas 114 serve as protective structures around each individual die within each unweakened area 113. The weakened areas 114 may be formed during the normal processing of circuit devices on the dies, e.g., via etching.

Such techniques, and other methods, may be used to instead place weakened path structures near the edge of the wafer for the purpose of directing unintentional cracks away from the product die, and thus confine cracks induced at the edge to regions near the wafer edge. Such weakened paths may thus be placed in or near the exclusion area, rather than between individual dies/chips, to protect the circuit-bearing portions of the wafer.

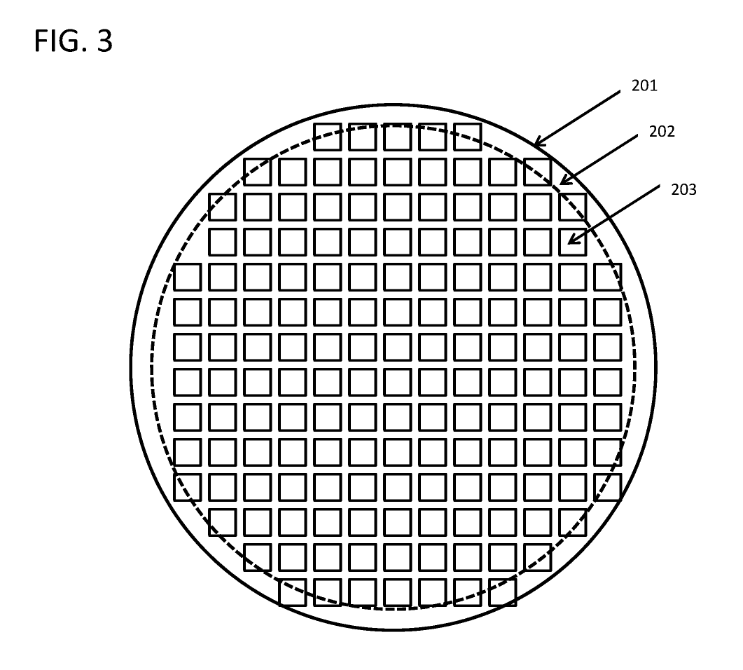

FIG. 3 shows an example wafer 201 having a weakened path 202 inset from the wafer perimeter and multiple dies 203. In the example of FIG. 3, the weakened path 202 and the wafer substrate 201 are circular. In practice, the weakened path may be of any shape, and be adjusted to fit the geometry of the substrate, or a portion thereof. For example, a weakened path 202 may follow the contours of a semiconductor wafers that is mostly round but has one or more flats or notches. Similarly, the weakened path 202 may follow the contour of a rectangular or oblong substrate. The weakened path 202 may be a continuous feature, such as a score or a groove, or a periodic feature, such as a series of perforations, such that the periods are close enough that a crack will divert to the path rather than pass between the periodic features.

The location of the weakened path 202 near the wafer edge, rather than around or between individual dies 203, provides the utility of stopping crack propagation during multiple processing steps. This placement of a weakened section near the wafer edge confines inward propagation of unintentional wafer edge cracks. This is in contrast to the weakened regions 102 of FIG. 1 and areas 114 of FIG. 2 which may inadvertently foster premature cracking of the wafer prior to singulation.

In the example of FIG. 3, the weakened path 203 traverses multiple dies 202, likely rendering them inoperable. This highlights that the use of the weakened path is not limited to wafers originally designed to encompass such a weakened path. Rather, a weakened path such as weakened path 202 may be added dynamically to any wafer at any point in wafer processing. This may be advantageous when, for example, issues of unexpected cracking are encountered for a particular design variant or process batch.

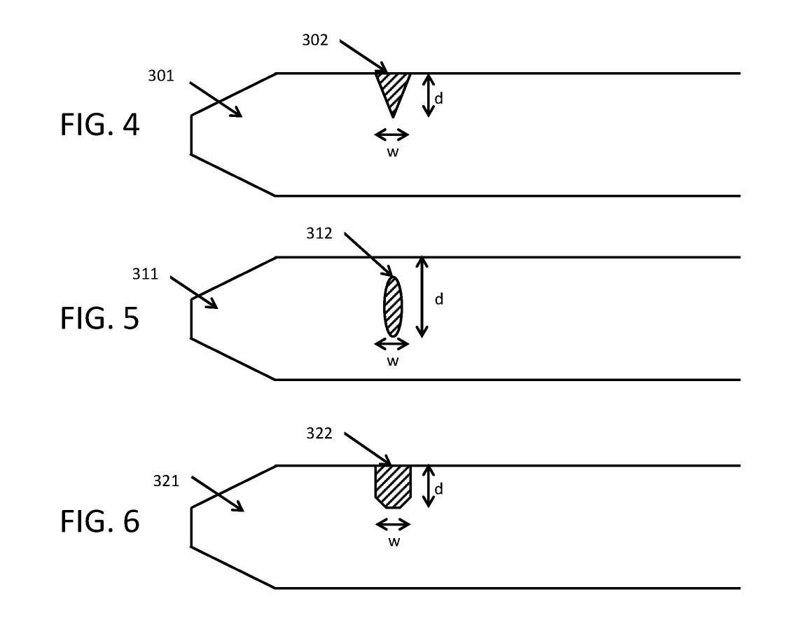

FIGS. 4, 5, and 6 show vertical cross-sections of the edges of example wafers 301, 311, and 321. In FIG. 4, a weakened path 302 takes the form of a V-shaped groove that is inset from the edge of wafer 301. Groove 302 may be through mechanical removal of material through dicing or laser ablation of the surface of the wafer 301, for example.

In FIG. 5, a weakened path 312 takes the form of a region of sub-surface damage in the wafer 311. The sub-surface damage 312 may be formed by laser processing, for example, or by patterned ion implantation, to create lattice damage.

In FIG. 6, a weakened path 322 takes the form of a trench. The weakened path 322 may be etched into the surface of wafer 321 through patterned plasma etching or wet etching, for example.

The processes used to form weakened paths may be used independently of each other or other wafer processing procedures. For example, the etching, ablation, or dicing used to create weakened paths may be done separately from the wafer processes that are used to create circuity on dies. Therefore the weakened path structures may be created at any time in the wafer process flow. Such structures may thereby protect the wafer throughout the entire process flow, or be added before a problematic process step, without adding complications to earlier process steps. This allows flexibility of adding the structure when it is needed, and not before.

Conversely, where desired, the creation of weakened path structures may be integrated with other wafer processing steps. If the wafer process includes a suitable etch process, for example, the weakened path may be formed during the etching of other wafer features.

Not shown in FIGS. 4, 5, and 6, the weakened paths may include periodic perforations extending entirely through the wafer. Alternatively, the weakened paths may include areas combining grooves, channels or trenches on both sides of the wafer, on both sizes and the center, or on one side and the center.

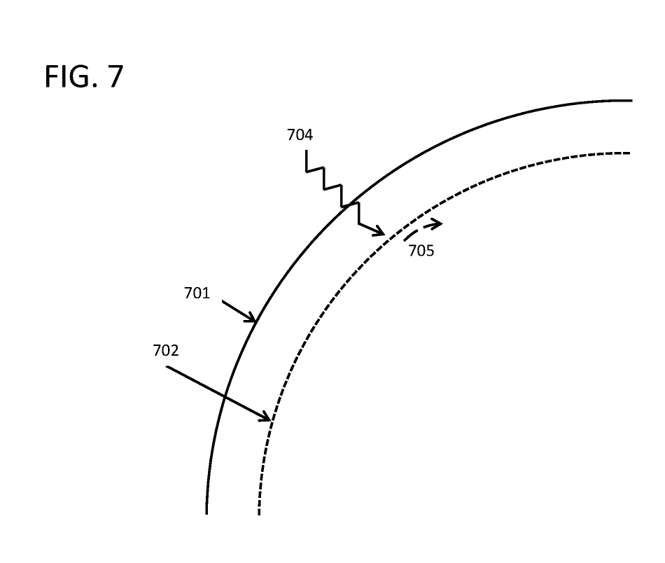

FIG. 7 show an example where an inset crack-stopping weakened path 702 prevents an accidental extrinsic edge crack 704 from reaching the center of the wafer 701. FIG. 7 shows a section of arc of the edge of a circular wafer 701. The crack 704 may begin, for example, due to a stress induced through manipulating the wafer 701, e.g., in transferring wafer 701 from one processing location to another. The crack continues to shear inwardly until it reaches the weakened path 702, and then begins to follow arc 705 along path 702, which is weaker than the rest of the wafer and gives with less force.

Weakened paths may be created by a variety or combination of techniques. For example, some sections of weakened path may be created using a combination of two more actions of dicing, laser ablation, ion implant, and etching. Some sections may be created by one of these means, while another section is created by a separate means, for instance.

The depth and size of a weakened path feature may be varied to optimally balance considerations of strength desired for nominal processing and the failure strength of the region for when extrinsic cracks occur. The geometry of the weakened paths may be optimized for the material system, tools and processes, and strength requirements for different products and manufacturing facilities. Further, the geometry may be varied at different areas of wafer, e.g., at a flat or notch as opposed to the general perimeter.

For example, early in the processing of a 350 um thick SiC wafer, a v-shaped groove may be cut to a depth of 100 um into the top side of the wafer. Later, the wafer may be thinned to 150 um. Alternatively, stealth dicing may be used to introduce internal perforations centered on the finished depth of the wafer, e.g., circa 75 um below the surface. This may be done from the front side while the wafer is at its full 350 um thickness, prior to backside thinning down to a final thickness of 150 um.

In practice, the depth of a weakened path crack stopping feature may vary widely, e.g., from 10% to 75% of the wafer thickness. For a 350 um thick wafer that will be polished to down to 100 um, the depth may be 10 to 75 um, for example. Depths of 35% to 70% of final wafer thickness may be more appropriate depending on specific materials and processes used, and depths of 50% to 65% of final wafer thickness may be sufficient to achieve the purpose of stopping cracks. Design considerations for the weakened path include, for example, whether the wafer will be handled by its edges or by vacuum attachment to its center.

The width of the crack stop feature may also vary widely. The exact width may be primarily determined by the technology used to create the crack stop feature. For example, the width of a groove or channel created by etching or ablation may be determined by the time or energy required to achieve the intended depth.

Different forms of weakened path crack stopping features may be employed for different materials, process steps, or stages of production. For example, where laser ablation is used to cut a surface groove into a wafer, there may be an area around the groove where the ablated material will land and adhere. This is called recast material. Removing the recast material may be done easily on gallium arsenide wafers using a wet etch. However, this may be less practical for other materials, such as silicon carbide. There, a solution may be to coat the wafer with a thin polymer prior to ablation to prevent the adhesion of recast material to the wafer itself, and then strip the polymer in water or a solvent, for example. Alternatively, a stealth dicing technique may be preferred to create the crack stop feature on a silicon carbide wafer.

In the case that a wafer has significant metallization near the wafer perimeter on the top surface, a laser ablation or stealth dicing approach from the front side may not be desirable. A stealth dicing process could be done from the wafer backside, if adequate protection is provided for topside circuit features, if any, during the backside processing, for example.

In describing embodiments of the subject matter of the present disclosure, as illustrated in the figures, specific terminology is employed for the sake of clarity. The claimed subject matter, however, is not intended to be limited to the specific terminology so selected, and it is to be understood that each specific element includes all technical equivalents that operate in a similar manner to accomplish a similar purpose.

This written description uses examples to disclose the invention, including the best mode, and also to enable any person skilled in the art to practice the invention, including making and using any devices or systems and performing any incorporated methods. The patentable scope of the invention is defined by the claims and may include other examples that occur to those skilled in the art. Such other examples are intended to be within the scope of the claims if they have structural elements that do not differ from the literal language of the claims, or if they include equivalent structural elements with insubstantial differences from the literal language of the claims.

We claim:

1. A semiconductor wafer, comprising a semiconductor substrate with a perimeter and a first scoring, the first scoring being inset from the perimeter and following the perimeter.

2. The semiconductor wafer of claim 1, wherein the first scoring comprises a first groove or a first trench on a first surface of the wafer.

3. The semiconductor wafer of claim 2, further comprising a second scoring, where the second scoring comprises a second groove or a second trench on a second surface of the wafer, such that the second scoring is opposite the first scoring.

4. The semiconductor wafer of claim 1, wherein the first scoring comprises a void or a lattice defect in the interior of the wafer.

5. The semiconductor wafer of claim 4, further comprising a second scoring, where the second scoring comprises a groove or a trench on a second surface of the wafer such that the second scoring is opposite the first scoring.

6. The semiconductor wafer of claim 1, wherein the first scoring comprises a series of periodic perforations in the semiconductor wafer.

7. The semiconductor wafer of claim 1, wherein the first scoring comprises a series of periodic regions of sub-surface damage in the semiconductor wafer.

8. The semiconductor wafer of claim 1, wherein the first scoring comprises substantially continuous sub-surface damage in the semiconductor wafer.
